(19) United States
(12) Patent Application Publication
(10) Pub. No.: US 2012/0279548 A1
(43) Pub. Date: Nov. 8, 2012

(54) ARRANGEMENT AND CIRCUIT, AND METHOD FOR INTERCONNECTING FLAT SOLAR CELLS

(76) Inventors: Markus Münch, Coswig (DE); Stefan Tegen, Dresden (DE)

(21) Appl. No.: 13/500,616

(22) PCT Filed: May 17, 2010
(86) PCT No.: PCT/DE2010/075040

§ 371 Date: Jul. 11, 2012

(30) Foreign Application Priority Data
May 18, 2009 (DE) 10 2009 025 828.0
May 17, 2010 (DE) 10 2010 016 975.7

(51) Int. Cl. H01L 31/05; H01L 31/18

(52) U.S. Cl. 136/244; 438/66; 257/E31.001

(57) ABSTRACT

The invention relates to an arrangement and circuit, and to a method for interconnecting flat rigid or flexible solar cells, the photoelectrical active layers thereof being applied to an insulating substrate material. The aim of the invention is provide a novel arrangement and circuit and an associated method for interconnecting flat solar cells, reducing the risk of short circuit and the inactive surface area in the matrix composite of the solar module and selectively allowing simple interconnection, both as a parallel circuit and as a series circuit in production. The solar cells (1) in the arrangement and circuit of flat rigid or flexible solar cells are disposed overlapping in the contact area to one or more adjacent solar cells (1). Said solar cells (1) are interconnected to each other directly once or a plurality of times in a novel manner, having a contact material (10) at the overlapping area to each other, used in contact material (10) or switching points (22).

The invention relates to an arrangement and a circuit as well as a method for connecting of the face like, rigid or flexible solar cells, the photoelectrical active layers thereof are applied onto an insulating substrate material, in particular for thin layer solar cells according to the preamble of the claims one, two, three and twelve. Face like solar cells using thin layer technology can be formed both rigid as well as also flexible. Similarly these solar cells can also be individual, discrete solar cells, however also several, so-called monolithically connected solar cells on a common substrate material.

The positive and negative contact of a solar cell can be disposed also on the same side of the solar cell (this concerns in addition to the here described solar cells for example also classic silicon back side contact cells). When connecting individual solar cells to a matrix of solar cells according to the present state of the art, the individual solar cells are arranged at a defined distance and are amongst each other contacted electrically with the special contact elements (conductor connectors) or flat conductors, as can be recognized from U.S. patent application publication U.S. 2005 0268959 and the German printed patent document DE 10 2006 019 68 A1. The arrangement with defined distances between the individual solar cells serves here for securing the process in order to avoid short circuits at the solar cell edge during production and during operation caused by a touching of the solar cells amongst each other. A substantial part of inactive face relative to the face of a solar cell matrix on a solar module is thereby generated, in particular in case of small solar cell dimensions, where the substantial part cannot be used for the absorption of the sunlight and for the energy conversion. During the connection of the individual solar cells care has to be given that in solar cell arrangements corresponding to the state of the art no short circuits at the solar cell edges by connection materials such as individual damaged or imprecisely disposed connectors, solder, solder paste, guide adhesive, or guide paste, which lead to the failure of the corresponding solar cells and finally to a substantial decrease in power of a solar cell matrix comprising a plurality of solar cells or of a complete solar module.

Furthermore, the optically not active back side contact region, however indispensable for the connection of the solar cells (in case of solar cells to be contacted from the front side), exhibits a relatively high part of the face of the inactive solar cell surface not serving for energy conversion. A number of different technical solutions for such solar cell arrangements are known, in order to connect these solar cell arrangements with a low loss in area of the active face. A solar cell module with the solar cells arranged in parallel and in series is known from the German printed patent document DE 37 08 548 A1, wherein the problem of an optimal connection is resolved by having the rows of solar cells overlapping and staggered with respect to each other arranged such that the solar cells are connected amongst each other in a series/parallel circuit. Here the back side of each solar cell row is connected in each case with the front side of the next solar cell side. It is a disadvantage of this solution that a soldering paste has to be applied in an intermediate step, that then the next row of the solar cells has to be precisely positioned and placed and that then the soldering has to be performed by way of a thermal process. Here, the solar cells are not allowed to shift relative to each other during the handling. The most essential disadvantage could be that in each case always only one solar cell row after the other can be placed on the base material and that then in each case the contact materials have to be applied prior to the placement of the next solar cell row.

Furthermore, a plurality of differently formed conduction connections is known for the connection of the individual solar cells to each other. A solar cell connector with a balancing section is described in the German printed patent document DE 102 35 048 A1, wherein the balancing section has a frame shaped structure and wherein a recess is disposed within the frame shaped structure. Voltage tips in the material are to be avoided by the closed frame structure. However this constructive building is laid out mechanically fixed and no spring properties of individual parts are possible with this construction despite the center recess. In addition, this technical solution requires substantial space for connecting of the individual solar cells to each other, since the individual neighboring solar cells in each case have to be disposed at a defined distance from each other.

A particular springing solar cell connector having Z-shape when seen from the side is known from the European patent application EP 1126 558 A2, wherein the solar cell connector has a fine member structure. The construction of the solar cell connector however is relatively expensive and exceeds in its height the upper edge of the solar cells to be connected to each other, this means that additionally the embedding material has to be further recessed at this location. This solar cell connector requires a particularly large space in order to obtain full effectiveness. The production of such a solar cell connector is in addition relatively expensive and its automatic installation including the contacting with the contact faces of the solar cells can be controlled only with difficulties.

Another flat constructing solar cell connector, which is to have similarly spring properties, is described in the European patent application 1037 309 A2. However torsion forces occur at the contact locations between the contact faces of the solar cell and the contact faces of the solar cell connectors, since the solar cell connectors are formed relatively broad and spring properties are more likely not to be expected. This solar cell connector also minimizes the material tensions only to a small degree and a tearing of the contacts can occur in case of large temperature variations after a relatively short operational time. Here again there is a large space requirement for the connection of neighboring solar cells as was the case with the already cited technical solutions.

The Japanese printed patent document JP 2001-30999 A describes a further curved solar cell connector for a spaceflight body, which in turn again projects and protrudes beyond the upper limiting face of the individual solar cells. Also the same disadvantages hold for this embodiment as for the preceding recited documents.

A massively formed, flat band like solar cell connector is described in the Japanese printed patent document JP 2005-19479 A, which connector extends over the full width of the slot, which slot is formed between two neighboring solar cells. This solar cell connector also has no spring properties. The solar cell connector is very broad formed and has relatively many contact positions with the contact faces of the individual, in each case neighboring solar cells to be contacted in order to allow at all a durable assurance of the contacting. The solar cell connector can be employed both for the connection of two front sides (front-front side contact) or also for connecting of front-back side contact of neighboring solar cells. However, with this construction the elasticity limit of the conductor connection material is also surpassed at longer tension and pressure loading such that a destruction of the contacting can occur.

It is an object of the invention to furnish a novel arrangement and connection circuit as well as an associated method for the contacting of face like solar cells, of their photoelectrical active layers, including of the contacts on an insulating substrate material, which reduces the risk of a short circuit and which reliably decreases the inactive area in the solar cell matrix compound, which enables selectively an easily variable simple shunt circuit as well as a row connection as also a series connection and which simplifies and accelerates the production process as well as the connection circuit as also the production process of solar cell modules from a plurality of individually each other contacting solar cells.

The object is resolved according to the present invention with the technical features of the first, the second, the third, and the twelfth patent claim. Advantageous embodiments of the main claim are part of the dependent sub claims. The arrangement and connection circuit of flat, rigid or flexible solar cells, the photoelectrical active layers of the solar cells, including the contacts are placed on an insulating substrate material 2 according to the present invention, the positive and negative contacts of the solar cells on one side, exclusively on one side of the face and/or on one side of the face and at one or, respectively, several front sides, the solar cells 1 are disposed overlapping in the contact region with one or several neighboring solar cells 1, as is already known. These solar cells 1 are immediately switch connected with a contact material 10 at the overlap region on top of each other once or several times in a novel way and fashion with the contact materials 10 or switch points 22, wherein the contact materials bridges the insulating substrate. The switching points can have an arbitrarily geometrical form as desired and for example also exhibit circular, square, or rectangular base faces.

The invention is particularly suitable for thin layer solar cells, which are applied to an insulating substrate material as for example such materials on the basis of amorphous and/or microcrystalline silicon, organic compounds, dyes, cadmium telluride, copper indium diselenide, copper indium gallium diselenide, copper indium diselenide, copper indium sulfide or other III-V semiconductors. Here the connecting circuit is exclusively only on of front side 18 or only on the back side 19 or between the front sides 20 or between one or several front sides 20 and a front side 18 or, respectively, a back side 19.

In each case an electrically conducting layer is generated by silk screen printing, dispensing, spraying on, vapor deposition, sputtering, or galvanic deposition with the aid of the invention method for circuit connection of flat solar cells and for production of contacts to the connection conduits for current discharge on a complete solar cell matrix from several overlapping solar cells 1 at individual or as needed selectively also at several (possibly also at multiple) switching points 22. This layer or, respectively, the corresponding number of the layers are then point wise at the corresponding locations so applied that in each case the back side contact 7 of the upper solar cell is connected to the front side contact 17 of the overlapping immediately neighboring solar cell 1. The arrangement of the contacts on the solar cell 1 is decisive for the performance of the contact. In the case where both the front side contact 17 as well as also the back side contact 7 are disposed in each case on the front side of the solar cell 1, wherein the contact material 10 is applied such that the contact material 10 reaches from the back side contact 7 over the front side of the solar cell up to the front side contact 17 of the overlapping next neighboring solar cell 1. If however the rear side contact 7 is disposed on a side at the front side 20 of the solar cell 1, then the contact material can be arranged only at the corresponding positions moving up from the front side to the front side contact 17 of the next solar cell 1. If the back side contact 7 however is disposed on the side of a frontal face 20 of the solar cell 1, then the contact material can only be disposed at the corresponding positions from the frontal face 20 up to the front side contact 17 of the next solar cell 1. The contact material can here be applied or arranged as a running through strand or as an individual or multiple contact in one or several switching points 22. The layer thicknesses and the layer widths of the contact material 10 of the contact material applied at the respective switching point 22 or the switching points 22 are dependent on the dimensioning of the individual solar cells 1 to be connected, the in each case generated and to be discharged currents and the material composition of the employed contact material 10. It is also possible to arrange the contact material 10 by placing of prefabricated contact materials 10 (for example the placing of contact elements) as switch connection at the respective switching points 22, connected with a following fixation, instead of the preceding described application of the contact material 10 onto the complete cell matrix.

A similarly equally ordered embodiment also belongs to the invention, wherein the contacting between two neighboring solar cells 1 through openings 21 completely going through and arranged in the solar cell (this means also penetrating the electrically insulating substrate material 2). According to this arrangement for circuit connection of face like, and out of rigid or flexible solar cells with positive and negative contact, the solar cells 1, as is already known in principle, are also disposed overlapping in the contact region with one or several neighboring solar cells 1. One or several (depending on the desired number of switch points 22) openings 21 penetrating the complete solar cell 1 are entered in the overlapping region in a novel kind and way, wherein the back side contact 7 of the solar cell 1 can be contacted in the openings 21, which means that the back side contact 7 is disposed such freely in the opening 21 that the back side contact 7 can be electrically contacting connected. A further possibility to increase the face of the contactable back side contact and thereby to improve the conductivity of the contacting comprises to remove around the openings photoelectrical active layers exclusively of the back side contact disposed on the insulating substrate material. Thereby free laid back side contact faces 24 are generated on the solar cell front side 18. An electrical connection is switched between back side contact 7 and the immediately below lying one or several front side contacts 17 in and/or at the openings 21 by way of contact material 10.

A reliable, durable and mechanically stable circuitry of overlapping solar cells becomes also possible. The advantage of the arrangements and of the corresponding method according to the invention versus the arrangements known from the state of the art comprises that the inactive face in the matrix compound of a solar module with the arrangement according to the invention and the overlaps associated therewith can be substantially minimized. The light absorbing face can be increased by up to 10 percent with this solution according to the present invention.

According to another variant of the arrangement and circuit connection of face-like, rigid or flexible solar cells with positive and negative contacts, wherein their photoelectrical active layers are applied to an insulating substrate material, the solar cells 1 in the contact region are in fact also overlapping disposed with one or several neighboring solar cells 1, however in the overlap region the photoelectrical active region excluding the back side contact 7 disposed on the insulating substrate material 2, is fully or partially removed or was not applied at all. They form in this case a free laid back side contact face 24. One or several openings 21 penetrating the substrate material 2 and the free laid back side contact face 24 are disposed here likewise in the overlap region. At and/or in the penetrating openings 21, the back side contact 7 of the solar cell 1 is formed contactable. An electrical connection between back side contact 7 and the immediately disposed below one or more front side contacts 17 are switched here at and/or in the respective openings 21 with contact material 10.

The openings 21 according to the present invention on one side of the solar cells 1 are disposed at a maximum distance of 5 mm from the edge of the solar cell 1, that is 5 mm distance along a long front side 20 of the solar cell 1 according to a preferred embodiment of the arrangement for circuit connecting of face like, rigid or flexible solar cells with positive and negative contacts.

It is sensible to switch-connect the individual overlapping solar cells 1 to be switched, linear staggered with respect to each other in order to be able to connect different circuit connections of the face like solar cells 1.

Here individual overlapping solar cells 1 depending on the application and the desired arrangement linear against each other can be staggered arranged and circuit connected by a value between 1 and 99 percent relative to the cell length 12. The arrangement and size of the required switching points 22 is decisive for the minimum overlap. The advantage consists in a better shading tolerance (translator's remark: should be “switching tolerance”) at individual solar cells 1 circuit connected to each other. Theoretically, the distance of the individual solar cells to be connected can also be larger, however there are required then particularly long conduit connectors or long strips of contact material for circuit connection amongst each other.

According to a particular preferred arrangement for circuit connecting of face like solar cells 1, the overlapping individual solar cells 1 to be circuit connected against each other, are arranged and circuit connected exactly half linear staggered relative to their dimension. The occurring cross currents can be distributed more uniformly in this situation.

In general, an arrangement for circuit connected of face like solar cells is also conceivable, wherein the individual overlapping solar cells 1 to be circuit connected are formed of different size are disposed linearly staggered with respect to their dimensions. In order to be able to exploit optimally the area present on the carrier material, there are furthermore additionally arranged and circuit connected face shaped smaller solar cells at the edges of a solar module including a multitude of overlapping solar cells 1. Very variable circuit connecting variations of the solar cells 1 of a solar module can be connected with an optimum face occupation and therewith maximized power delivery.

It is for the first time possible based on the invention solution to furnish a novel arrangement for the circuit connection of face like solar cells and to put the arrangement to use, wherein the individual overlapping solar cells 1 to be circuit connected or arrangements of solar cells which are staggered relative to each other and circuit connected within a row at a distance from each other in the sense of a checkers board pattern. Also other geometric arrangements and forms such as for example writing characters, symbols or numbers are conceivable.

A further novel arrangement for circuit connecting of face like solar cells 1 can be produced by arranging the individual overlapping solar cells 1 to be circuit connected and staggered to each other in the sense of a parquet pattern and are connected to each other according to the present invention.

According to a particular embodiment of the invention solution the individual overlapping solar cells 1 can be arranged and circuit connected on a one or two dimensional convex and/or concave curved surface of a carrier material or also even onto a cylinder face. In this manner such solar cells can also be attached to surfaces and surface shapes which in the past did not appear to be suitable. Now it is for example possible to place solar cells without problem onto cylindrical surfaces or otherwise curved and moving surfaces, which means surfaces which are continuously or also discontinuously subjected to light. Completely new application faces can be opened up with the solar cell matrix compounds according to the invention or correspondingly equipped solar modules.

Depending on the position and arrangement of the solar cell contact to be contacted amongst each other, the method for the circuit connecting of face like solar cells can be modified such that the circuit connecting of the overlapping solar cells 1 takes place either only on the front side 18 or only on the back side 19 of the solar cells 1 or between the frontal sides 20 or between one or several frontal sides 20 and a front or, respectively, back side 18, 19 or the inner side of an opening 21 and a front or, respectively, back side 18, 19.

It is advantageous if in the method for circuit connected of face like solar cells on to the complete cell matrix out of several overlapping solar cells 1 at the switching points 22, the electrically conductive layers, which produce the contracting, are generated by way of silkscreen printing, dispensing, spraying lawn, vapor deposition, sputtering, or galvanic deposition simultaneously and in a single process step or if in another performance of the method the contact materials 10 are simultaneously and in a single process step laid down and fixed onto the complete cell matrix at the switching points 22.

According to the process also in the circuit connection of face like solar cells onto the complete cell matrix of several overlapping solar cells 1 at the switching points 22 the electrically conducting contact materials serving for contacting are placed and fixed with the aid of a combination of two or several methods, such as by way of silkscreen printing and/or dispensing and/or spraying on and/or vapor deposition and/or sputtering and/or galvanic depositing onto the complete cell matrix at the switching points 22, wherein the contact materials 10 are placed and fixed onto the complete cell matrix.

In a special, particularly advantageous and timely effective method for circuit connecting of flat solar cells there can simultaneously be performed, that is in one process step, a complete metallization of the cell matrix, of the positive solar cell contacts 4, the negative solar cell contacts 5, the contact finger 6 and the circuit connection of the solar module after the arrangement and fixation of the overlapping solar cells 1 on the carrier material (for example on a back side glass).

It is particularly advantageous in the method for circuit connecting of face like solar cells 1 if in the contact material 10 for circuit connecting of the overlapping solar cells 1 to amongst each other is the same material as the material for solar cell metallization as also the complete other circuit connection of the solar module (that is the contact material 10 at the switching points 22).

The short circuit risk is reliably used in the arrangement according to the present invention and the corresponding method, since the positive contact in the circuit connection region includes both the surfaces of the solar cells as well as the cell edges in the matrix compound. In particular also a durable and quickly produced circuit connection with only the most simple materials such as for example conductive pastes and/or conductive adhesives or the like by printing on or dispensing or, respectively, vapor deposition is possible. This means as an advantage the dispensing with the up to now necessary circuit connectors, which had to be produced as additional parts in the kind of connection bandlets/stamping parts, punched parts or the like.

As a further method advantage, the cell metallization and the circuit connection can be realized in principle nearly simultaneously and in a single process step. In case of solar cells contacted only on one side, that is the back side contact is led on the front side of the solar cell, then the contacting ditch 8 in the region of the positive solar cell contact 4 can be completely dispensed with, since the cell front side with the metallization is short circuited at the edge of the solar cell over the connector material. This is associated with the consequence that the width of the back side contact region of the cell surfaces is further reduced and the installation ditch 9 can be positioned closer to the cell edge. The production without a problem of both pure series connection as well as series parallel connection of the individual solar cells amongst each other represents a further substantial advantage of the invention method. Series parallel connections have the advantage that by the flow of cross currents the shading tolerance (translator's remark: should be “switching tolerance”) can be improved. This results in a lower power loss at part shadings (translator's remark: should be “switching”) and includes the so-called hot spot behavior of the solar cell circuit. The invention method opens in addition the possibility to be able to apply the total metallization of the solar cell matrix (busbars, contact finger, and circuit connection) only after the arrangement of the solar cells on the carrier material in a single process step.

The novel arrangement according to the invention and the associated method for circuit connecting of face like solar cells reliably decreases the risk of a short circuit. The inactive area in the solar cell matrix compound or in a solar module can be reduced substantially, which increases the power yield. In addition and depending on need the circuit connection without problem as a row circuit as well as a series circuit as well as a row parallel circuit can be adapted to the application situation desired in each case. Overall the production process of a solar cell matrix compound, and circuit connection process and also the production process of large area solar cell modules out of a plurality of individual solar cells contacted amongst each other is simplified and accelerated.

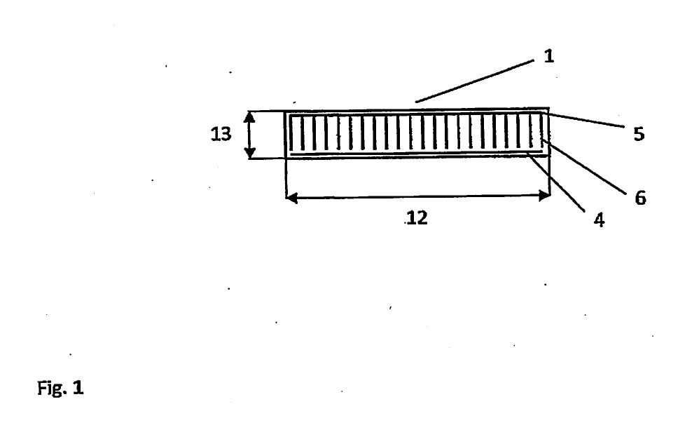

The invention is in the following more specifically illustrated in various embodiment variations by way of FIGS. 1 through 14.

FIG. 1 shows a top planar view on to a face like discrete solar cell 1

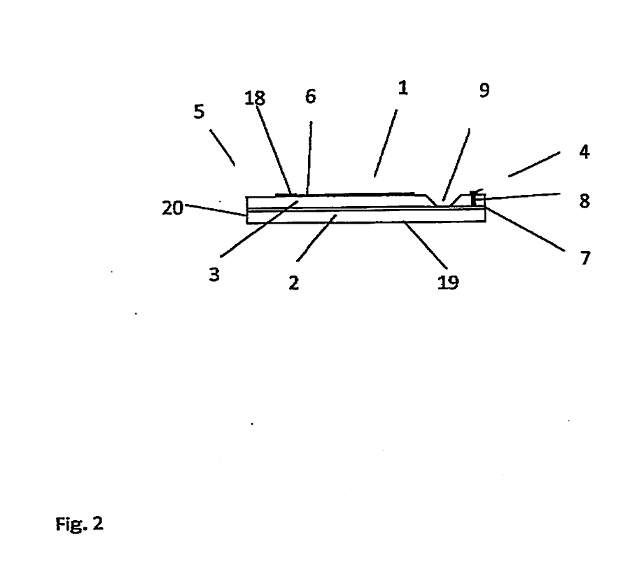

FIG. 2 shows a side section through a face like discrete solar cell 1

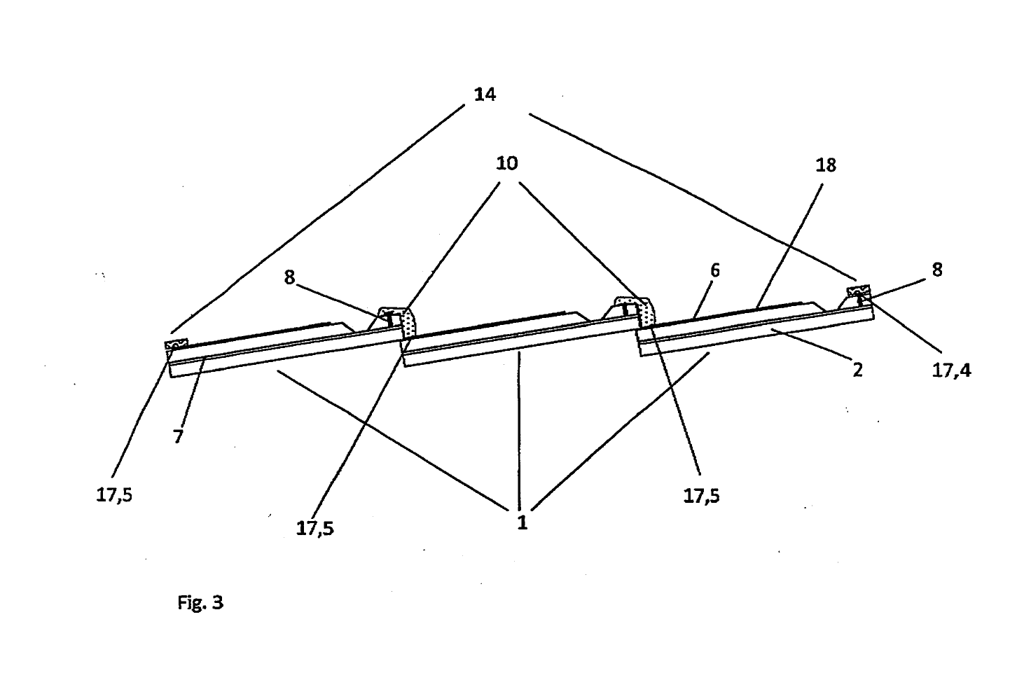

FIG. 3 shows a sectional view of three neighboring and overlapping each other solar cells 1 with connection conductors 14 on the front side 18

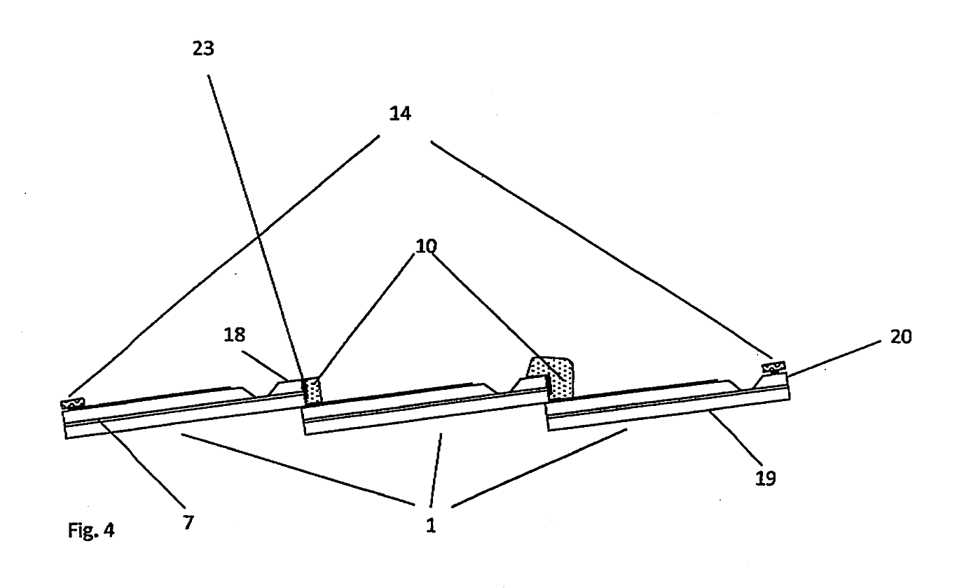

FIG. 4 shows a sectional view of three neighboring and overlapping solar cells 1 with connection conductors 14 on the front side 18 and frontal face side contacting

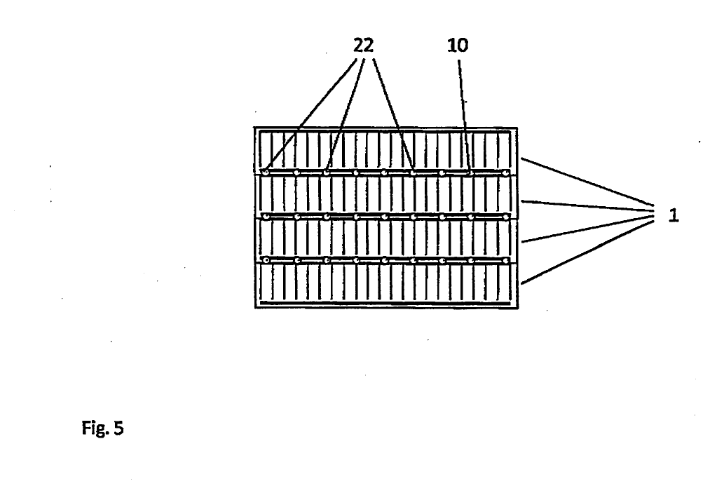

FIG. 5 shows a top planar view of four next to each other overlapping arranged and circuit connected solar cells 1 with in each case nine switching points 22 per solar cell 1

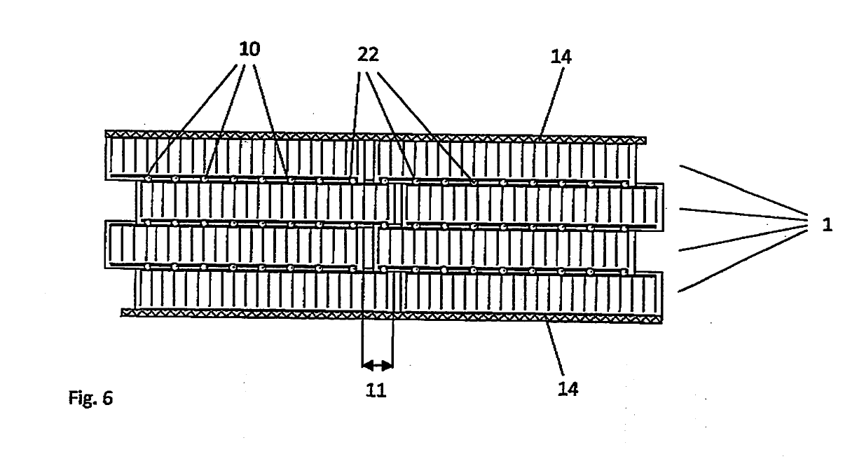

FIG. 6 shows a top planar view of eight next to each other overlapping and staggered arranged and circuit connected solar cells 1 with in each case nine switching points 22 per solar cell 1

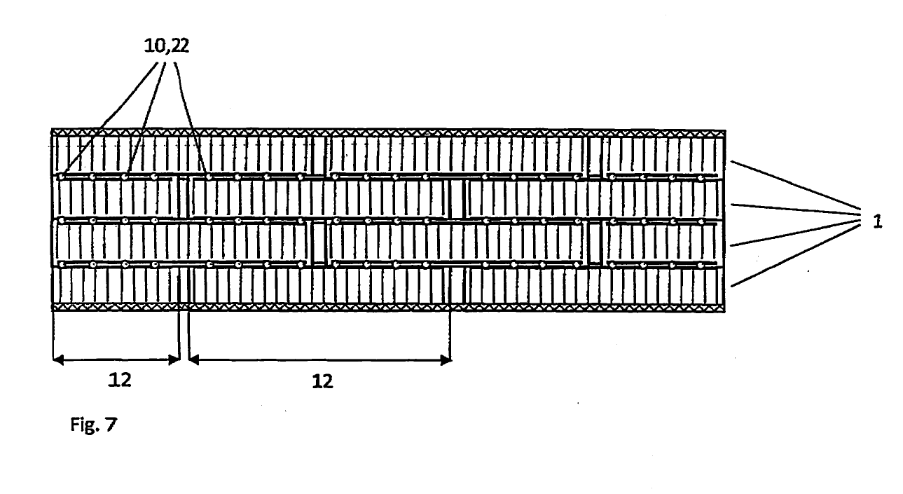

FIG. 7 shows a top planar view onto a solar cell matrix with four rows of next to each other disposed, staggered overlapping and circuit connecting solar cells 1

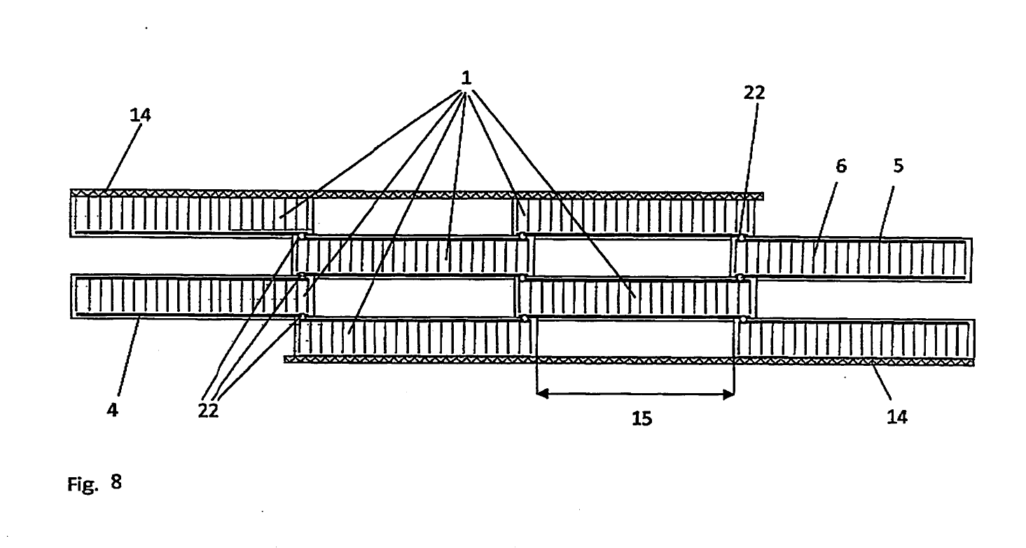

FIG. 8 shows an arrangement of four rows of solar cells 1 with a very large distance 15 between two solar cells 1 within a row

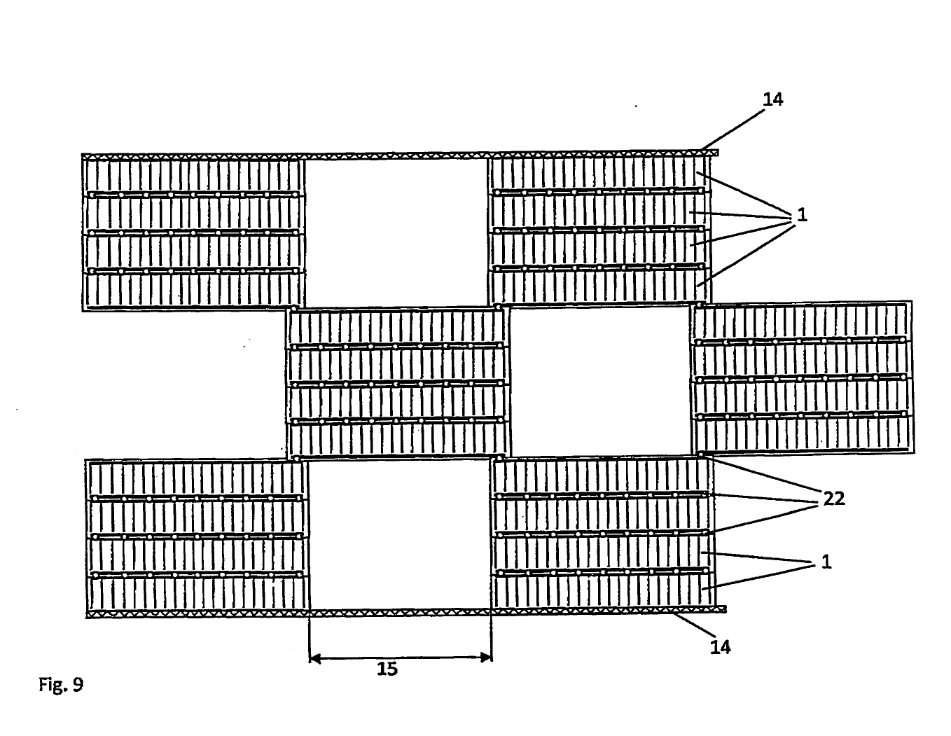

FIG. 9 shows a top planar view onto a solar cell matrix compound in the row parallel circuit connection grouped solar cell 1

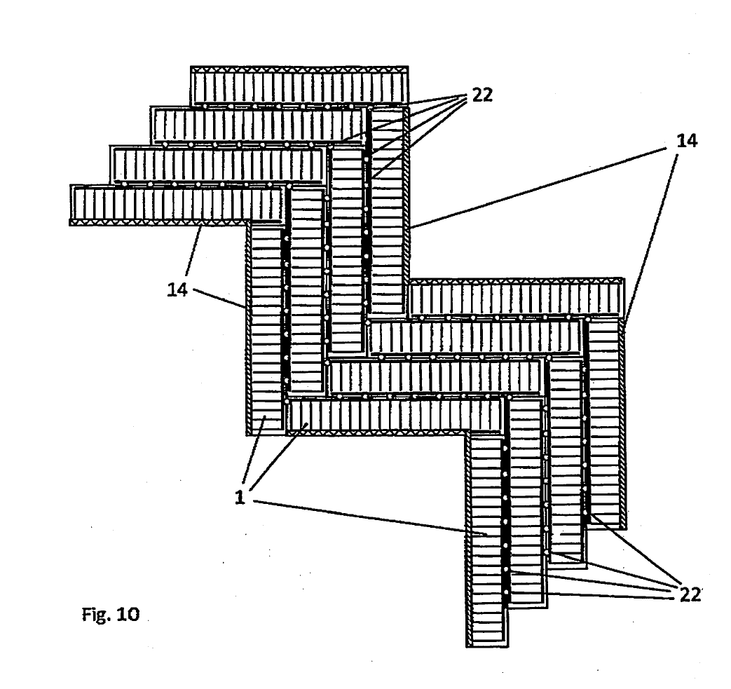

FIG. 10 shows an arrangement of solar cells 1 in the kind of parquet pattern including their circuit connection amongst each other

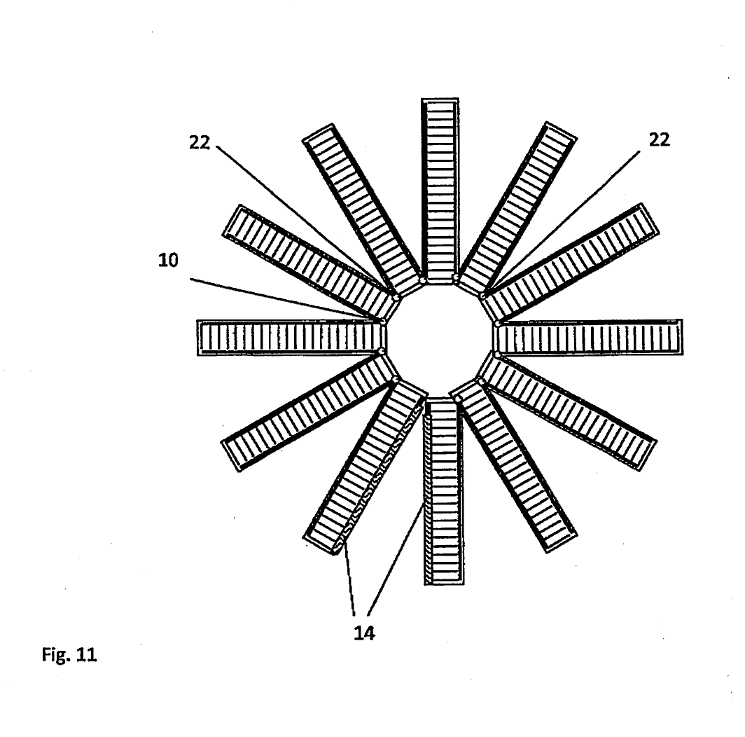

FIG. 11 shows an arrangement of ray shaped outwardly arranged solar cells 1 with only minimal overlapping and with contact material 10 at only in each case a switching point 22 for solar cell 1

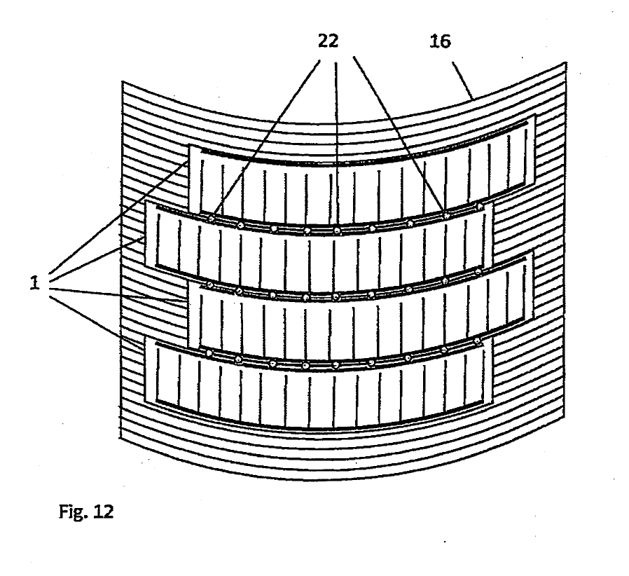

FIG. 12 shows as staggered overlapping arrangement of four solar cells 1 of a convex curved surface of an arched carrier material 16

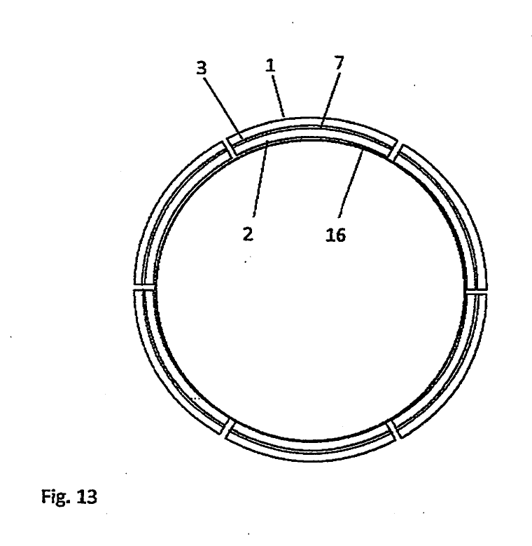

FIG. 13 shows a sectional view of solar cells 1 arranged on a surface of a cylinder, which solar cells 1 are overlapping each other in the depth

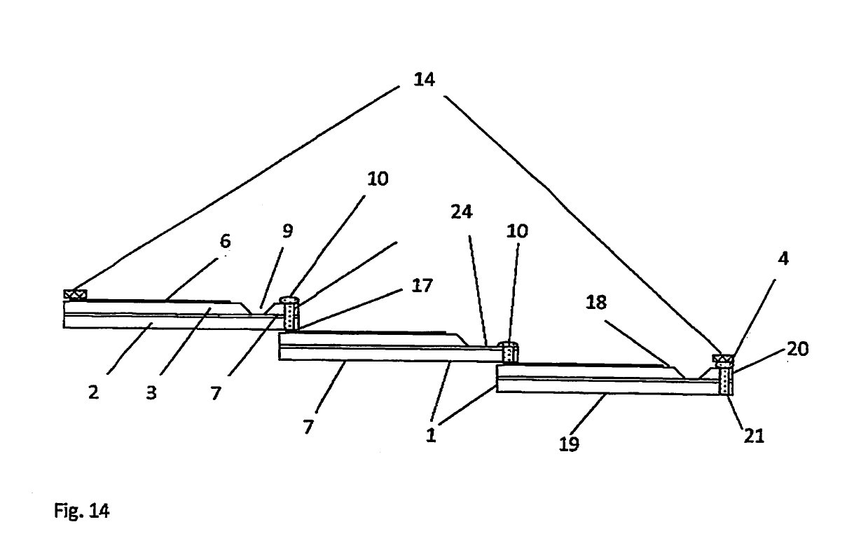

FIG. 14 shows a sectional view of three neighboring solar cells 1 overlapping each other with openings 21 according to the invention, and contact material 10 brought into these openings 21 and the back side contact face 24 laid open

A preferred construction of a face like solar cell 1 from a top planar view according to FIG. 1 and from the cross sectional view according to FIG. 2, and in fact of a copper indium galium diselenide thin layer solar cell with pure front side contacts and insulating substrate is illustrated, which means the two contacts 4 and 5 are disposed and can be seen on the surface of the front side 18. Usually, the length of the cell 12 is a multiple of the width of the cells 13. The positive solar cell contact 4 is disposed on the front side 18 along the long side of the solar cell 1. This positive solar cell contact 4 is conductively connected to the back side contact 7 by way of a contacting in the contacting ditch 8, wherein the back side contact 7 is disposed between the absorber layer 3 and the substrate material 2. The negative solar cell contact 5 is disposed on the front side 18 along the other long side, wherein the negative solar cell contact 5 connects the individually cross disposed contact fingers 6, which contact fingers 6 collect the generated current from the active absorber face and feed the current to the negative solar cell contact 5. The insulating ditch 9 is placed next to the negative solar cell contact 5 in the absorber layer 3, wherein the insulating ditch 9 separates the absorber layer at this position in order to prevent short circuits between the ends of the contact finger 6 and the negative solar cell contact 5. The insulating ditch 9 can here be led up to the ends of the surface of the back side contact 7. The area of the substrate material 2 is of the same size as the area which the material has, which forms the active absorber layer 3 such that a flat shaped frontal side 20 is generated. The back side 19 of the substrate material 2 is preferably furnished with an additional adhesive layer (not shown in the drawing). It is thereby possible to fix immediately precisely and immovable the individual solar cell 1 at the arrangement on a carrier material.

A sectional view of three neighboring and overlapping solar cells 1 is shown in FIG. 3 with connection conductors 14 on the front side 18. The positive solar cell contact 4, which is provided as the front side contact 17, is conductively connected to the front side contact 17, 5 by way of contacts 10. Here, the positive solar cell contact 4 is connected to the negative solar cell contact 5 through contact material 10 such that the contact material 10 covers both the positive solar cell contact 4 as well as also the negative solar cell contact 5. Here the contact material is led over the complete frontal side 20. Practically the positive solar cell contact 4 is conductively connected for a second time at the frontal side 20, which further increases the safety of the connection. The contact material 10 can, as needed, be applied and hardened as a small area switching point or also as selected as a kind of switching strip going through. For delivery of the generated current from the solar cell matrix compound consisting here of three rows disposed solar cells 1 located behind each other, the collection conductors 14 are disposed in each case left and right outside on the front side contacts 17, which means a positive and a negative solar cell contact 4 and 5 can be variably connected for current disposition towards the outside of the solar cell matrix compound.

Another embodiment of the contacting 10 according to the present invention is illustrated in FIG. 4. This shows a sectional representation of three neighboring and overlapping solar cells 1 with collection conductors 14 on the front side 18, and in contrast to above now with frontal side contacting with in the arrangement of pure frontal side contacts 23 for the back side contact 7. The contact material 10 can here selectively be placed and hardened either only from the frontal side contact 23 to the front side contact 17 of the negative solar cell contact 5 or grips fully over the frontal side 20 and further in part, covers the surface of the non-active absorber material on the circuit connection side of the solar cell 1.

A top planar view of four successively and overlapping arranged and circuit connected solar cells 1 with in each case nine switching points 22 for each solar cell 1 is shown in FIG. 5 such that a solar cell matrix compound is generated of four solar cells 1. The contacting material 10 is here point like along the circuit connection side distributed applied and hardened, whereby a defined number of individual switching points 22 at a distance from each other is formed. The number of the switching points 22 depends here on the dimensioning of the individual solar cells 1 and the current generated in each case. Based on safety considerations it is sensible to arrange in each case several switching points 22 for each overlap such that in case of a possible interruption or bad contacting of one or two switching points 22, the remaining switching points are still able to support an operating current flow and each individual solar cell 1 can generate power.

FIG. 6 shows a top planar view of eight next to each other and overlapping and staggered with a small step 11 arranged and circuit connected solar cells 1 with in each case nine switching points 22 for each solar cell 1, such that a solar cell matrix compound out of eight solar cells with a row parallel circuit is generated. The arrangement of the two required collection conductors 14 is shown here, where the generated electrical current can be fed to the outside with the collection conductors 14.

The illustration according to FIG. 7 shows a top planar view onto a possible solar cell matrix with four rows of next to each other disposed, half staggered overlapping and circuit connected solar cells 1, wherein four solar cells have a shorter cell length 12, with point shaped disposed contact material 10 such that for each long solar cell 1 eight switching points 22 are formed and for each shorter solar cell 1 four switching points 22 are formed. As a result there is generated a rectangular solar cell matrix compound consisting out of eight large long and four short, practically half long solar cells 1.

Another embodiment of the various circuit connection possibilities is shown in FIG. 8, where there is shown an arrangement of four rows of solar cells 1 with a very large distance 15 (larger than 90 percent of the cell length 12) between two solar cells 1 within a row of a solar cell matrix compound and wherein the extremely staggered disposed individual solar cells in each case are arranged with only one switching point 22 per positive or, respectively, negative solar cell contact 4 or, respectively, 5. A higher light through-put can be adjusted thereby. The collection conductors 14 are placed and formed going through. The light transmitting area can be varied as desired over a broad range.

Another possibility how also to vary the light transmission is shown in FIG. 9. Here in each case four solar cells 1 are grouped and circuit connected among each other in series and several solar cell groups are connected to a solar cell matrix compound as a series parallel circuit.

It is also conceivable and possible to connect the arrangement of individual solar cells 1 according to FIG. 8 with an arrangement in solar cell groups according to FIG. 9. In addition to a setting of each arbitrary light transmission here, also various differently formed optical patterns can be generated. In addition there exists the possibility to form at certain locations a clearly transmitting larger area and to generate therewith a kind of a window.

A completely different arrangement of solar cells 1 into a kind of parquet pattern is shown in FIG. 10. Here again the individual solar cells 1 are disposed in part overlapping and are, as already several times described, connected among each other with a certain number of switching points 22. The collection conductors 14 are here in part interrupted in order to avoid reliably short circuits along the cell width 13. The contacting by way of contact material 10 is such that all individual solar cells 1 disposed at right angles to each other as a kind of parquet pattern are arranged staggered relative to each other and are connected as a special series-parallel circuit. This way different non-conventional novel optical appearance pictures of solar cell arrangements can be generated.

The arrangement according to FIG. 11 represents an example for this, wherein the FIG. 11 shows an arrangement of solar cells 1, which are directed outwardly like rays, where is only a minimum overlap and with the concentration of the contact material 10 and the circuit connection can be realized only at or, respectively, in each case of a switching point 22 per solar cell 1.

A staggered overlapping arrangement of four solar cells 1 on a convexly curved surface of an arched carrier material 16 is shown in FIG. 12. Also such applications on curved surfaces are without problem realizable with the invention arrangement and the production invention method.

An arrangement of surfaces of cylinders is also possible as shown in FIG. 13. In this exemplary sectional view thereof six solar cells 1 laid onto and positioned on a cylindrical carrier material 16. The overlapping of the switched solar cells is not illustrated here, since the solar cells overlap along their depth and are according to the invention circuit connected among each other in series-parallel circuits at the overlap positions.

An embodiment according to claim 12 is shown in a sectional view in FIG. 14. Three neighboring solar cells 1 overlap here for example. According to the invention, one or several as selected, passing through openings 21 are brought into these overlapping solar cells in a novel kind and fashion in the edge strip, which edge strip is disposed on the right hand side next to the installation ditch 9. These openings 21 penetrate the absorber material 2, the backside contact 7, that is the positive solar cell contact 4 and the substrate material 2. They reach up to the backside 19 of the solar cell 1. Alternatively, the photo electrically active layers, with the exception of the backside contact, disposed on the insulating substrate material, can be removed, or in the first place not applied at all in the range of the openings 21. Free laid backside contact faces 24 are hereby generated on the solar cell front side 18. The openings 21 then penetrate exclusively the substrate material 2 and the backside contact 7. Based on this construction the backside contact 7 does not have to be led upwardly on the front side 18 as the front side contact 17 or sideways toward the outside at the frontal side 20 as frontal side contact 23. The backside contact 7 is disposed within the and/or around the openings 21 such free that the backside contact 7 can be electrically conducting connected by way of the contact material 10. An electrical connection between backside contact 7 and the immediately below disposed one or several front side contacts 17 of the neighboring solar cells 1 practically as a kind of switching pin is connected at and/or in the openings 21 by way of contact material 10. It is advantageous in connection with the circuit that the insulating ditches 9 can be led around the switching points 22 such that the light converting face of the solar cell becomes substantially enlarged. A further enlargement of this face can be achieved by removing or first not at all applying absorber layer 3 around the switching points 22, and the insulating ditch 9, which runs along a solar cell side and is formed through going, thus becomes dispensable.

### LIST OF REFERENCE CHARACTERS

1 solar cell
2 substrate material
3 absorber layer
4 positive solar cell contact
5 negative solar cell contact
6 contact finger
7 back side contact
8 contacting ditch with contacting of the positive solar cell contact to the backside contact
9 insulating ditch
10 contact material
11 staggering
12 length of solar cell
13 width of solar cell
14 collection conductor
15 distance in longitudinal direction
16 arched carrier material
17 front side contact
18 front side
19 backside
20 frontal side
21 openings
22 switching point
23 frontal side contact
24 backside contact face laid free

1. Arrangement and circuit of face like, rigid, or flexible solar cells, wherein the photoelectrical active layers thereof are applied to an insulating substrate material, the positive and negative contacts are disposed on one side, exclusively on the side of the face, and/or side of the face and at one or several frontal sides,
characterized in that
the solar cells (1) are disposed overlapping in the contact region with the one or several neighboring solar cells (1),
the solar cells (1) are circuit connected once or several times with a contact material (10) at the overlap region, wherein the contact material bridges over the insulating substrate and
the switching is performed exclusively on a front side (18) or only on the backside (19) or between the frontal sides (20) or between one or several frontal sides (20) and a front side or a backside (18, 19).

2. Arrangement and circuit of face like, rigid, or flexible solar cells, with positive and negative contacts, the photoelectrical active layers thereof are applied to an insulating substrate material,
characterized in that
the solar cells (1) are arranged in the contact region with one or several neighboring solar cells (1),
wherein one or several openings (21) are disposed penetrating the complete solar cell (1) in the overlap region,
wherein the backside contact (7) of the solar cell (1) cell can be contacted,
and wherein an electrical connection between the backside contact (7) and the immediately lying below one or several front side contacts (17) is switched at and/or in the openings (21) by way of the contact material (10).

3. Arrangement and circuit of face like, rigid, or flexible solar cells with positive and negative contacts, wherein the photoelectrical active layers of the solar cells are applied to an insulating substrate material,
characterized in that
the solar cells (1) are disposed overlapping with one or several neighboring solar cells (1) in the contact region,
wherein the photoelectrical active layers exclusive of the backside contact 7 disposed on the insulating substrate material 2 are completely or in part removed in the overlap region or were not applied and thereby form a free laid backside contact face 24,
wherein one or several openings (21) penetrate the substrate material 2 and the free laid backside contact face 24 and
are disposed in the overlap region,
wherein the backside contact (7) of the solar cell (1) can be contacted at and/or in which openings (21), and at and/or in the openings (21) there is connected an electrical connection between the backside contact (7) and the immediately lying below one or several front side contacts (17) by way of the contact material (10).

4. Arrangement and circuit of face like, rigid, or flexible solar cells, with positive and negative contacts according to claim 2, characterized in that
the openings (21) are disposed on one side to the solar cells (1) with a maximum 5 mm distance from the solar cell edge.

5. Arrangement and circuit of face like, rigid, or flexible solar cells according to claim 1,
characterized in that
the individual overlapping solar cells (1) connected to a circuit are disposed linear staggered against each other and circuit connected.

6. Arrangement and circuit of face like, rigid, or flexible solar cells according to claim 5,
characterized in that
the individual overlapping solar cells (1) switching connected are disposed and circuit connected linear staggered against each other by a value between 1 to 99 percent with respect to the cell length (12).

7. Arrangement and circuit of face like, rigid, or flexible solar cells according to claim 5,
characterized in that
the individual overlapping solar cells (1) to be switch connected are disposed and circuit connected against each other and are disposed exactly half linear staggered with reference to their dimensions.

8. Arrangement and circuit of face like, rigid, or flexible solar cells according to claim 5,
characterized in that
overlapping solar cells (1) to be circuit connected are formed of different size in their dimensions and are disposed linear staggered relative to the dimensions and in addition smaller face solar cells are disposed and switch connected at the edges of a solar module made of a plurality of overlapping solar cells (1).

9. Arrangement and circuit of face like, rigid, or flexible solar cells according to claim 5,
characterized in that
the individual overlapping solar cells (1) or solar cell arrangements to be circuit connected are disposed staggered relative to each other and are circuit connected at a distance from each other within a row-series in the sense of a checker board pattern.

10. Arrangement and circuit of face like, rigid, or flexible solar cells according to claim 5,
characterized in that
the individual overlapping solar cells (1) are disposed staggered relative to each other at a right angle and are arranged and switch connected in the sense of a parquet pattern.

11. Arrangement and circuit of face like, rigid, or flexible solar cells according to claim 5,
characterized in that
overlapping solar cells (1) are disposed and circuit connected on a one or two dimensional convex and/or concave curved surface of a curved carrier material or on a cylindrical face.

12. Method for circuit connection of face like, rigid, or flexible solar cells and for generating contacts to the collector conductors f and or current discharge,
characterized in that
the complete solar cell matrix out of several overlapping solar cells (1) receives electrically conducting layers by way of silk screen printing, dispensing, spraying on, evaporating, sputtering, or galvanic deposition at an individual or several (multiple) switching points (22) or that contact material (10) is placed on and fixed onto the complete solar cell matrix at the switching points (22).

13. Method for circuit connection of face like, rigid, or flexible solar cells according to claim 12,
characterized in that
the switching connection of the overlapping solar cells (1) is performed only on the front side (18) or only on the backside (19) of the solar cells or between the frontal sides (20) or between one or several frontal sides and a front or backside (18, 19) or at and/or in an opening (21) and a front or rear side (18, 19).

14. Method for circuit connection of face like, rigid, or flexible solar cells according to claim 12,
characterized in that
electrically conducting layers are generated by silk screen printing, dispensing, spraying on, vapor deposition, sputtering, or galvanic deposition simultaneously in a single process step onto the complete solar cell matrix out of several overlapping solar cells (1) at the switching points (22), or that the contact materials (10) are laid on and fixed in a single work step onto the complete solar cell matrix at the switching points (22).

15. Method for circuit connection of face like, rigid, or flexible solar cells according to claim 12,
characterized in that
electrically conducting layers are laid on and fixed onto the complete solar cell matrix out of several overlapping solar cells (1) at the switching points (22) with the aid of a combination of two or more methods such as silk screen printing and/or dispensing and/or spraying on and/or vapor deposition and/or sputtering and/or galvanic deposition, and contact materials (10) are laid on and fixed onto the complete cell matrix at the switching points (22).

16. Method for circuit connection of face like, rigid, or flexible solar cells according to claim 12,
characterized in that
a complete metallization of the cell matrix of the solar module (busbars, the contact finger and the circuit) is performed simultaneously in a single process step after the arrangement and fixation of the overlapping solar cells (1) on the carrier material (2).

17. Method for circuit connection of face like, rigid, or flexible solar cells according to claim 12, characterized in that
the contact material (10) for the circuit connected of the overlapping solar cells (1) among each other is the same material as the material for the solar cell metallization.
